(19) United States
(12) Patent Application Publication
(10) Pub. No.: US 2026/0314305 A1
(43) Pub. Date: Oct. 8, 2026

(54) SUBSTRATE PROCESSING APPARATUS

(71) Applicant: EBARA CORPORATION, Tokyo (JP)

(72) Inventors: Masayuki SATAKE, Tokyo (JP); Jumpei FUJIKATA, Tokyo (JP); Masashi SHIMOYAMA, Tokyo (JP)

(21) Appl. No.: 19/152,890

(22) PCT Filed: Jan. 22, 2024
(86) PCT No.: PCT/JP2024/001597

§ 371 Date: Jun. 25, 2026

(30) Foreign Application Priority Data
Feb. 7, 2023 (JP) 2023-016554

(51) Int. Cl. H10P 72/00

(52) U.S. Cl. CPC H10P 72/0448; H10P 72/0606; H10P 72/0616

(57) ABSTRACT

The present invention relates to a substrate processing apparatus for applying a filler to a gap between edge portions of substrates constituting a laminated substrate. The substrate processing apparatus for applying the filler (F) to the laminated substrate (Ws) having a first substrate (W1) and a second substrate (W2) bonded to each other, includes: a substrate holding device (2) configured to hold and rotate the laminated substrate (Ws); and a multi-nozzle head (20) configured to apply the filler (F) to a gap (G) between an edge portion (E1) of the first substrate (W1) and an edge portion (E2) of the second substrate (W2). The multi-nozzle head (20) includes a plurality of liquid jet nozzles (21) configured to emit the filler (F), and the plurality of liquid jet nozzles (21) are arranged along a rotation axis (Ct) of the substrate holding device (2).

### TECHNICAL FIELD

The present invention relates to a substrate processing apparatus for applying a filler to a gap between edge portions of substrates constituting a laminated substrate.

### BACKGROUND ART

In recent years, in order to achieve higher density and higher functionality in semiconductor devices, three-dimensional packaging technology, in which substrates are laminated and integrated three-dimensionally, has been developed. For example, in the three-dimensional packaging technology, a device surface of a first substrate on which integrated circuits and electrical wires are formed is bonded to a device surface of a second substrate on which integrated circuits and electrical wires are formed. After the first substrate is bonded to the second substrate, the second substrate is thinned by a polishing apparatus or a grinding apparatus. In this manner, integrated circuits can be stacked in a direction perpendicular to the device surfaces of the first substrate and the second substrate.

In the three-dimensional packaging technology, three or more substrates may be bonded to each other. For example, a third substrate may be bonded to the second substrate after the second substrate bonded to the first substrate has been thinned, and then the third substrate may be thinned. In this specification, a form of substrates bonded to each other may be referred to as a “laminated substrate”.

Generally, an edge portion of a substrate is polished in advance to have a rounded shape or a beveled shape in order to prevent cracking or chipping of the edge portion. When the second substrate having such a shape is ground (thinned), an acute edge is formed in the second substrate as a result of grinding. This acute edge (hereinafter referred to as a knife-edge portion) is constituted of a ground back surface and a circumferential surface of the second substrate. Such a knife-edge portion is likely to be chipped by a physical contact, and the laminated substrate itself may be broken during transportation of the laminated substrate. Furthermore, insufficient bonding between the first substrate and the second substrate may cause the second substrate to be cracked during grinding.

Thus, a filler is applied to the edge portion of the laminated substrate before the second substrate is ground in order to prevent the knife-edge portion from cracking or chipping. The filler is applied to a gap between an edge portion of the first substrate and an edge portion of the second substrate. The filler can support the knife-edge portion that has been formed after the second substrate is ground, and can prevent cracking or chipping of the knife-edge portion.

### CITATION LIST

### Patent Literature

Patent document 1: Japanese laid-open patent publication No. 2022-38834

### SUMMARY OF INVENTION

### Technical Problem

As shown in FIG. 18, application of the filler to the gap between the edge portion of the first substrate and the edge portion of the second substrate is performed by ejecting filler F filled in a syringe 121 of an application device 103 from a filler emitting port 122 while rotating a laminated substrate Ws. The laminated substrate Ws is held by a substrate holding device (not shown). The laminated substrate Ws is rotated about its own center by the substrate holding device. The application device 103 intermittently emits droplets of the filler F from the filler emitting port 122 toward the gap of the laminated substrate Ws.

If the droplets of the filler F emitted from the filler emitting port 122 are large, liquid splashing may occur when the droplets of the filler F fall onto the laminated substrate Ws, or voids may be generated in the filler F that has been applied. Further, in the application device 103 having a single syringe 121, if an abnormality, such as clogging of the filler F in the syringe 121, occurs, the use of the application device 103 is forced to be interrupted, so that the filler F may not be stably applied to the laminated substrate Ws.

Therefore, the present invention provides a substrate processing apparatus capable of appropriately and stably applying filler to a gap between an edge portion of a first substrate and an edge portion of a second substrate.

### Solution to Problem

In an embodiment, there is provided a substrate processing apparatus for applying a filler to a laminated substrate having a first substrate and a second substrate bonded to each other, comprising: a substrate holding device configured to hold and rotate the laminated substrate; and a multi-nozzle head configured to apply the filler to a gap between an edge portion of the first substrate and an edge portion of the second substrate, wherein the multi-nozzle head includes a plurality of liquid jet nozzles configured to emit the filler, and the plurality of liquid jet nozzles are arranged along a rotation axis of the substrate holding device.

In an embodiment, the plurality of liquid jet nozzles are arranged across the laminated substrate in a thickness direction of the laminated substrate held by the substrate holding device.

In an embodiment, an arrangement pitch of the plurality of liquid jet nozzles is smaller than a width of the gap.

In an embodiment, at least two of the plurality of liquid jet nozzles are arranged in an emitting position facing the gap.

In an embodiment, an arrangement length of the plurality of liquid jet nozzles is larger than a thickness of the laminated substrate,

In an embodiment, the substrate processing apparatus further comprises: an operation controller configured to individually control emitting operations of the plurality of liquid jet nozzles.

In an embodiment, the substrate processing apparatus further comprises: an imaging device configured to generate an image of the gap, wherein the operation controller is configured to select, based on the image, a liquid jet nozzle to emit the filler from among the plurality of liquid jet nozzles.

In an embodiment, the operation controller is configured to select, based on an application state of the filler in the gap on the image, a liquid jet nozzle to emit the filler from among the plurality of liquid jet nozzles.

In an embodiment, the operation controller is configured to: detect a position of the gap in a thickness direction of the laminated substrate based on the image, and select, based on the detected position of the gap, a liquid jet nozzle to emit the filler from among the plurality of liquid jet nozzles.

In an embodiment, the imaging device is arranged upstream of the plurality of liquid jet nozzles in a rotation direction of the laminated substrate.

In an embodiment, the substrate processing apparatus further comprises: a nozzle moving mechanism configured to move the plurality of liquid jet nozzles; and an abnormality detection device configured to detect an abnormality in the plurality of liquid jet nozzles, wherein the operation controller is configured to control an operation of the nozzle moving device, and the operation controller is configured to cause the nozzle moving mechanism to move the plurality of liquid jet nozzles such that a liquid jet nozzle in which an abnormality has been detected by the abnormality detection device moves in a direction away from an emitting position facing the gap.

In an embodiment, the plurality of liquid jet nozzles are arranged obliquely with respect to a thickness direction of the laminated substrate held by the substrate holding device.

In an embodiment, the substrate holding device includes a plurality of substrate holding mechanisms configured to hold and rotate a plurality of laminated substrates, and at least a part of the plurality of liquid jet nozzles is arranged in a plurality of emitting positions facing a plurality of gaps of the plurality of laminated substrates.

In an embodiment, the plurality of jet nozzles are arranged across the plurality of laminated substrates in a thickness direction of the plurality of laminated substrates held by the plurality of substrate holding mechanisms.

### Advantageous Effects of Invention

According to the present invention, the multi-nozzle head includes the plurality of liquid jet nozzles configured to emit the filler, so that a droplet having an appropriate size can be emitted from each liquid jet nozzle without reducing an amount of the filler F emitted per unit time by the multi-nozzle head. Furthermore, according to the present invention, even if an abnormality occurs in any of the liquid jet nozzles, the filler can be stably applied to the gap between the edge portion of the first substrate and the edge portion of the second substrate by using other liquid jet nozzles.

### BRIEF DESCRIPTION OF DRAWINGS

FIG. 1A is a cross-sectional view showing an example of an edge portion of a laminated substrate to be processed;

FIG. 1B is a cross-sectional view showing an example of the edge portion of the laminated substrate to which a filler has been applied;

FIG. 1C is a cross-sectional view showing an example of the edge portion of the laminated substrate that has been thinned after the filler is applied;

FIG. 2 is a schematic diagram showing an embodiment of a substrate processing apparatus;

FIG. 3 is a diagram viewed from a direction indicated by an arrow A in FIG. 2;

FIG. 4 is an enlarged view schematically showing a plurality of liquid jet nozzles;

FIG. 5 is a plan view showing an arrangement of the plurality of liquid jet nozzles shown in FIG. 4;

FIG. 6 is a plan view showing another embodiment of the arrangement of the plurality of liquid jet nozzles;

FIG. 7 is a plan view showing another embodiment of a multi-nozzle head;

FIG. 8 is a plan view showing still another embodiment of the multi-nozzle head;

FIG. 9 is a schematic diagram showing an example of a manner in which the plurality of liquid jet nozzles apply the filler to a gap of the laminated substrate;

FIG. 10 is a schematic diagram showing an example of an image of the gap of the laminated substrate generated by an imaging device;

FIG. 11 is a schematic diagram showing another embodiment of the manner in which the plurality of liquid jet nozzles apply the filler to the gap of the laminated substrate;

FIG. 12 is a schematic diagram showing still another embodiment of the manner in which the plurality of liquid jet nozzles apply the filler to the gap of the laminated substrate;

FIG. 13 is a schematic diagram showing another embodiment of an application system;

FIG. 14 is a diagram illustrating an embodiment of a method of detecting an abnormality in the plurality of liquid jet nozzles;

FIG. 15 is a schematic diagram showing an example of an image of a test plate subjected to test application generated by an abnormality detection imaging device;

FIG. 16 is a diagram illustrating an embodiment of a method of moving the plurality of liquid jet nozzles when an abnormality is detected in a liquid jet nozzle by an abnormality detection device;

FIG. 17 is a schematic diagram showing another embodiment of the substrate processing apparatus; and

FIG. 18 is a schematic diagram showing a conventional substrate processing apparatus.

### DESCRIPTION OF EMBODIMENTS

Hereinafter, embodiments of the present invention will be described with reference to the drawings.

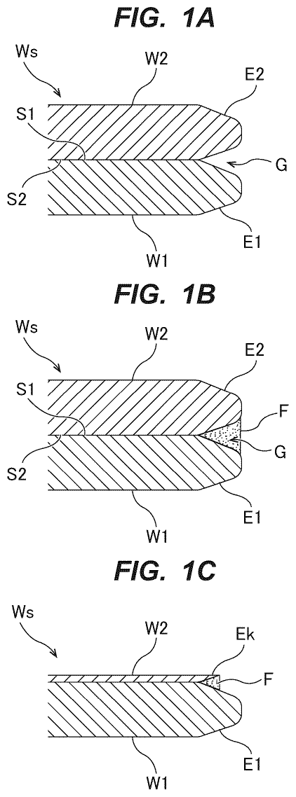

FIG. 1A is a cross-sectional view showing an example of an edge portion of a laminated substrate Ws to be processed. As shown in FIG. 1A, the laminated substrate Ws includes a first substrate W1 and a second substrate W2 bonded to each other. Each of the first substrate W1 and the second substrate W2 for use in this embodiment has a circular shape.

An edge portion E1 of the first substrate W1 is a portion constituting an outermost circumferential surface inclined with respect to a bonding surface (e.g., a device surface) S1 of the first substrate W1. More specifically, the edge portion E1 of the first substrate W1 has a rounded shape or a beveled shape. Similarly, an edge portion E2 of the second substrate W2 is a portion constituting an outermost circumferential surface inclined with respect to a bonding surface (e.g., a device surface) S2 of the second substrate W2. More specifically, the edge portion E2 of the second substrate W2 has a rounded shape or a beveled shape. Each of the edge portions E1 and E2 may be referred to as a bevel portion. A gap G is formed between the edge portion E1 of the first substrate W1 and the edge portion E2 of the second substrate W2. The edge portion of the laminated substrate Ws includes the edge portion E1 of the first substrate W1 and the edge portion E2 of the second substrate W2.

FIG. 1B is a cross-sectional view showing an example of the edge portion of the laminated substrate Ws to which a filler F has been applied. The filler F is applied to the gap G between the edge portion E1 of the first substrate W1 and the edge portion E2 of the second substrate W2. This gap G is formed over the entire circumference of the laminated substrate Ws, and has an approximately triangular cross section. The filler F is applied so as to fill this gap G.

FIG. 1C is a cross-sectional view showing an example of the edge portion of the laminated substrate Ws that has been thinned after the filler F is applied. As a result of this thinning process, a knife-edge portion Ek is formed in the edge portion E2 of the second substrate W2. Since the knife-edge portion Ek is held (or supported) by the filler F, the knife-edge portion Ek is prevented from cracking or chipping.

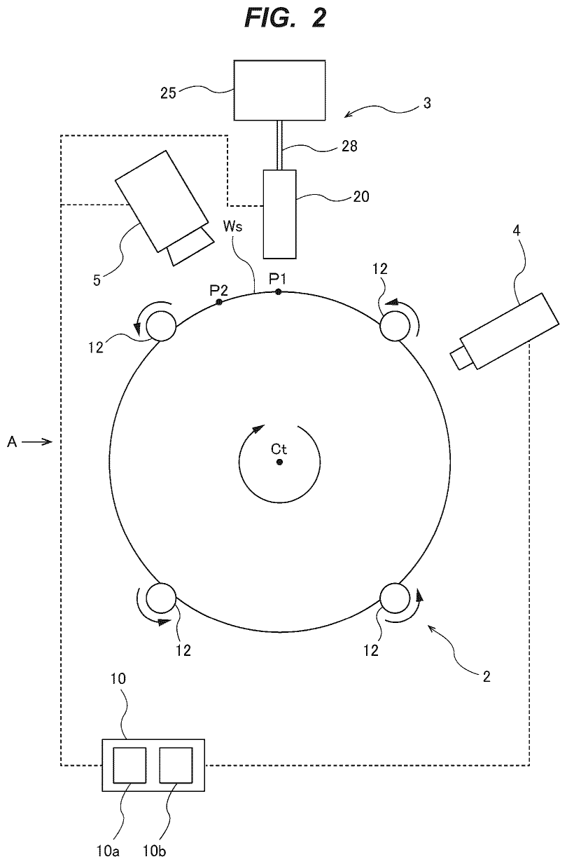

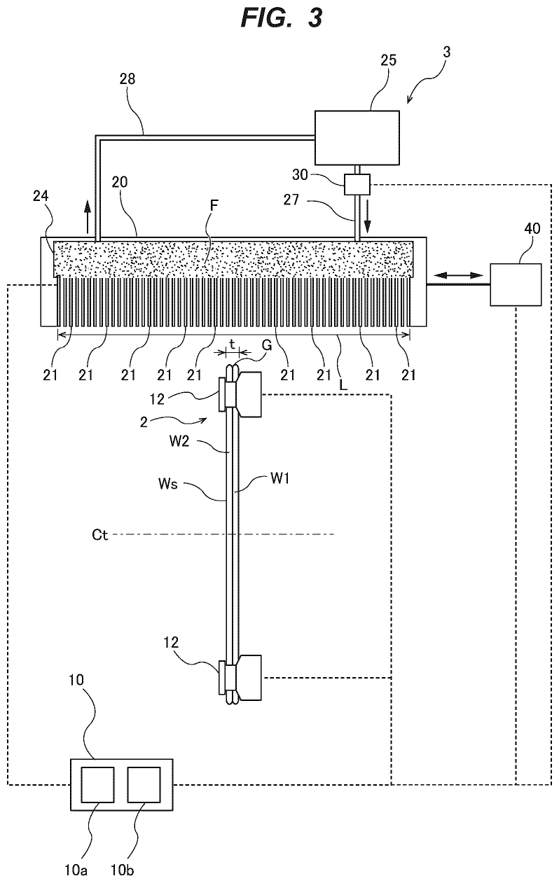

FIG. 2 is a schematic diagram showing an embodiment of a substrate processing apparatus, and FIG. 3 is a diagram viewed from a direction indicated by an arrow A in FIG. 2. The substrate processing apparatus is an apparatus for applying the filler F to the laminated substrate Ws having the first substrate W1 and the second substrate W2 which have been bonded. The substrate processing apparatus includes a substrate holding device 2 configured to hold the laminated substrate Ws in a vertical posture and rotate the laminated substrate Ws held thereby, an application system 3 configured to apply the filler F to the laminated substrate Ws, a curing device 4 configured to cure the applied filler F, and an imaging device 5 configured to generate an image of the gap G of the laminated substrate Ws.

The substrate holding device 2 includes a plurality of (in this embodiment, four) rollers 12 which can contact a periphery of the laminated substrate Ws, and a roller rotating mechanism (not shown) configured to rotate the rollers 12 about their respective own axes. In this embodiment, the substrate holding device 2 includes the four rollers 12, while the substrate holding device 2 may include three rollers, or five or more rollers.

The four rollers 12 contact the periphery of the laminated substrate Ws to hold the laminated substrate Ws such that a flat portion of the laminated substrate Ws is perpendicular to a horizontal plane. Therefore, the laminated substrate Ws is held in the vertical posture by the substrate holding device 2. The roller rotating mechanism is coupled to the four rollers 12, and is configured to rotate the four rollers 12 in the same direction at the same speed. The four rollers 12 are rotated by the roller rotating mechanism, so that the laminated substrate Ws is rotated about a rotation axis Ct of the substrate holding device 2 in a direction indicated by an arrow in FIG. 2. The configuration of the roller rotating mechanism is not limited as long as the plurality of rollers 12 can be rotated in the same direction at the same speed, and any known rotating mechanism can be used as the roller rotating mechanism. An example of the roller rotating mechanism is a combination of a motor, pulleys (and/or gears), and a rotating belt.

In one embodiment, the substrate holding device 2 may include, instead of the plurality of rollers 12, a holding stage (not shown) configured to hold a back surface of the laminated substrate Ws, and the laminated substrate Ws may be held by the holding stage such that the flat portion of the laminated substrate Ws is perpendicular to the horizontal plane. In this case, the substrate holding device 2 includes, instead of the roller rotating mechanism, a rotating shaft (not shown) coupled to a central portion of the holding stage, and a stage rotating mechanism (not shown) configured to rotate the holding stage and the rotating shaft. The stage rotating mechanism rotates the holding stage and the laminated substrate Ws held by the holding stage together about the rotation axis Ct of the substrate holding device 2.

As shown in FIG. 3, the application system 3 includes a multi-nozzle head 20 configured to apply the filler F to the gap G between the edge portion E1 of the first substrate W1 and the edge portion E2 of the second substrate W2, a filler supply source 25 configured to store the filler F to be applied to the gap G between the edge portion E1 of the first substrate W1 and the edge portion E2 of the second substrate W2, a filler supply line 27 configured to supply the filler F from the filler supply source 25 to the multi-nozzle head 20, a flow-rate regulating device 30 attached to the filler supply line 27, and a filler return line 28 configured to return the filler F from the multi-nozzle head 20 to the filler supply source 25.

The multi-nozzle head 20 is located radially outwardly of the laminated substrate Ws held by the substrate holding device 2, and is arranged above the laminated substrate Ws. The filler supply line 27 is coupled to the filler supply source 25 and the multi-nozzle head 20. The multi-nozzle head 20 has, in an interior thereof, a filler chamber 24 which communicates with the filler supply line 27. The filler F in the filler supply source 25 flows through the filler supply line 27, and is supplied to the filler chamber 24 of the multi-nozzle head 20. The flow-rate regulating device 30 is configured to regulate a flow rate of the filler F flowing through the filler supply line 27.

The filler return line 28 is coupled to the multi-nozzle head 20 and the filler supply source 25. The filler chamber 24 communicates with the filler return line 28, and a part of the filler F supplied to the filler chamber 24 is returned to the filler supply source 25 through the filler return line 28. In this manner, the filler F circulates between the filler supply source 25 and the filler chamber 24 through the filler supply line 27 and the filler return line 28.

The multi-nozzle head 20 includes a plurality of liquid jet nozzles 21 communicating with the filler chamber 24. A part of the filler F in the filler chamber 24 is supplied to the plurality of liquid jet nozzles 21. The plurality of liquid jet nozzles 21 are configured to emit the filler F supplied from the filler chamber 24.

The plurality of liquid jet nozzles 21 are arranged along the rotation axis Ct of the substrate holding device 2. An arrangement direction of the plurality of liquid jet nozzles 21 is parallel to the rotation axis Ct of the substrate holding device 2 or is oblique with respect to the rotation axis Ct of the substrate holding device 2 when viewed from above these liquid jet nozzles 21. In this embodiment, the arrangement direction of the plurality of liquid jet nozzles 21 is parallel to the rotation axis Ct of the substrate holding device 2. The plurality of liquid jet nozzles 21 are arranged across the laminated substrate Ws in a thickness direction of the laminated substrate Ws held by the substrate holding device 2. An arrangement length L of the plurality of liquid jet nozzles 21 is larger than a thickness t of the laminated substrate Ws. The arrangement length L of the plurality of liquid jet nozzles 21 is a distance between two liquid jet nozzles 21 located at both ends, and includes widths of the two liquid jet nozzles 21 themselves located at both ends.

The multi-nozzle head 20 emits the filler F from at least a part of the plurality of liquid jet nozzles 21 toward the gap G of the laminated substrate Ws, so that the multi-nozzle head 20 can apply the filler F to the gap G. Application of the filler F by the multi-nozzle head 20 is performed while the laminated substrate Ws is rotated by the substrate holding device 2. The filler F may be applied while the laminated substrate Ws is rotated multiple times depending on a total amount of the filler F to be applied.

The application system 3 further includes a nozzle moving mechanism 40 configured to move the multi-nozzle head 20 (the plurality of liquid jet nozzles 21). As shown in FIG. 3, the nozzle moving mechanism 40 is coupled to the multi-nozzle head 20, and is configured to move the plurality of liquid jet nozzles 21 of the multi-nozzle head 20 in the arrangement direction (i.e., in the thickness direction of the laminated substrate Ws). In this embodiment, the nozzle moving mechanism 40 is configured to move the plurality of liquid jet nozzles 21 of the multi-nozzle head 20 parallel to the rotation axis Ct of the substrate holding device 2. Examples of the nozzle moving mechanism 40 include a combination of a linear mechanism (e.g., a ball screw mechanism) and a motor (e.g., a servo motor, a stepping motor, etc.), and a linear electric actuator (e.g., a linear motor, etc.).

As shown in FIG. 2, the curing device 4 is located radially outwardly of the laminated substrate Ws held by the substrate holding device 2, and is arranged so as to face the gap G of the laminated substrate Ws. The curing device 4 is disposed downstream of the multi-nozzle head 20 of the application system 3 in a rotation direction of the laminated substrate Ws. The curing device 4 is configured to cure the filler F that has been applied to the laminated substrate Ws by the multi-nozzle head 20. Curing of the filler F by the curing device 4 is performed while the laminated substrate Ws is rotated by the substrate holding device 2. In this embodiment, the filler F has thermosetting property. An example of such a filler is a thermosetting resin.

The filler F includes a binder, a solvent, and particles. The particles are dispersed in the binder dissolved in the solvent. For example, a composition of the filler F is determined from a type of the binder, an amount of the solvent, an amount of the particles, or a size of each of the particles. Examples of the binder include inorganic binder containing alkali metal silicate, organic binder made of silicone resin or epoxy resin, and an inorganic-organic hybrid binder, The particles are, for example, particles of silica or alumina. The particles are mixed into the binder to increase a volume of the filler F and to adjust a viscosity of the filler F. In order to reduce the viscosity of the filler F, the particles may not be contained in the filler F.

The curing device 4 in this embodiment is an air heater, which is configured to emit hot air toward the filler F applied to the laminated substrate Ws. The filler F heated with the hot air is cured by a crosslinking reaction. When the filler F contains a solvent, the solvent is volatilized by the heating. The curing device 4 is not limited to the air heater, and may be a lamp heater or other configuration as long as the curing device 4 can heat and cure the filler F.

In this embodiment, the filler F has thermosetting property, while in one embodiment, the filler F may have ultraviolet curable property. In this case, the curing device 4 may be a UV irradiation device configured to cure the filler F by emitting ultraviolet light. When the filler F contains a solvent, the curing device 4 may heat the filler F to volatilize the solvent with an air heater or the like, in addition to the UV irradiation device.

As shown in FIG. 2, the imaging device 5 is located radially outwardly of the laminated substrate Ws held by the substrate holding device 2, and is arranged so as to face the gap G of the laminated substrate Ws. The imaging device 5 is located upstream of the multi-nozzle head 20 of the application system 3 in the rotation direction of the laminated substrate Ws. A position of the imaging device 5 is fixed. The imaging device 5 is configured to generate an image of the gap G of the laminated substrate Ws. In this embodiment, the imaging device 5 is configured to generate an image of the gap G located at a position P2 upstream of a position P1 directly below the multi-nozzle head 20 in the rotation direction of the laminated substrate Ws. An example of the imaging device 5 is a camera including an image sensor, such as a CMOS sensor or a CCD sensor.

The substrate processing apparatus further includes an operation controller 10 configured to control operations of the substrate holding device 2, the application system 3, the curing device 4, and the imaging device 5. The substrate holding device 2, the application system 3 (more specifically, the flow-rate regulating device 30, the nozzle moving mechanism 40, and a plurality of liquid emitting mechanisms 35 to be described later), the curing device 4, and the imaging device 5 are electrically coupled to the operation controller 10.

The operation controller 10 is composed of at least one computer. The operation controller 10 includes a memory 10a storing programs therein, and a processor 10b configured to perform arithmetic operations according to instructions contained in the programs. The memory 10a includes a main memory, such as a random-access memory (RAM), and an auxiliary memory, such as a hard disk drive (HDD) or a solid state drive (SSD). Examples of the processor 10b include a CPU (central processing unit) and a GPU (graphic processing unit). However, the specific configuration of the operation controller 10 is not limited to these examples.

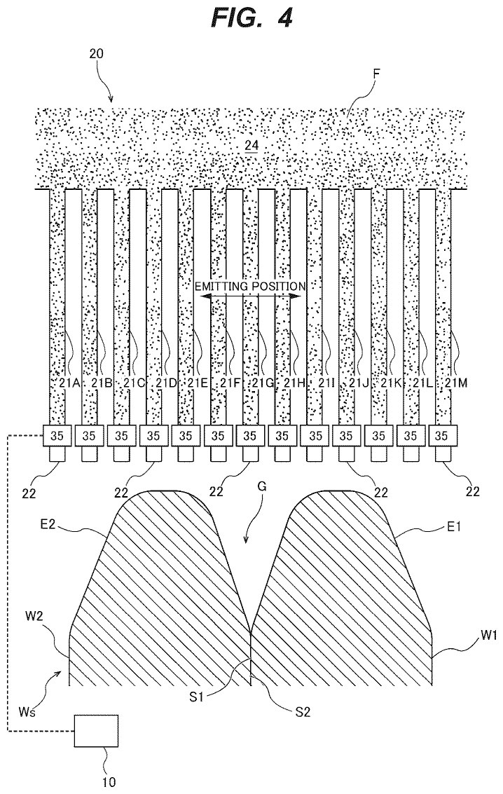

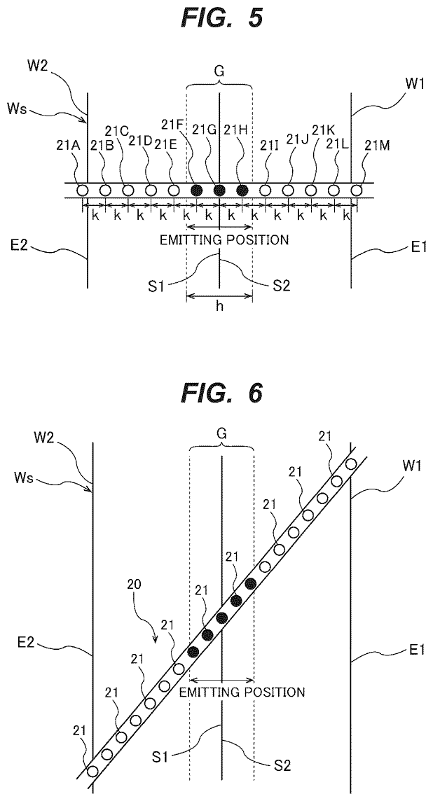

FIG. 4 is an enlarged view schematically showing the plurality of liquid jet nozzles 21, and FIG. 5 is a plan view showing an arrangement of the plurality of liquid jet nozzles 21 shown in FIG. 4. In FIGS. 4 and 5, a plurality of (in this embodiment, 13) liquid jet nozzles 21A to 21M of the multi-nozzle head 20 located adjacent to the laminated substrate Ws are shown. Configurations of these 13 liquid jet nozzles 21A to 21M will be described below, while all of the plurality of liquid jet nozzles 21 of the multi-nozzle head 20 have the same configurations. The plurality of liquid jet nozzles 21A to 21M are arranged parallel to the thickness direction of the laminated substrate Ws. The plurality of liquid jet nozzles 21A to 21M are arranged across the laminated substrate Ws in the thickness direction of the laminated substrate Ws. As shown in FIG. 5, the plurality of liquid jet nozzles 21A to 21M are arranged at equal intervals with an arrangement pitch k in the thickness direction of the laminated substrate Ws. The arrangement pitch k of the plurality of liquid jet nozzles 21A to 21M is smaller than a width h of the gap G between the edge portion E1 of the first substrate W1 and the edge portion E2 of the second substrate W2.

At least two of the plurality of liquid jet nozzles 21 are arranged in an emitting position facing the gap G between the edge portion E1 of the first substrate W1 and the edge portion E2 of the second substrate W2. The emitting position is a position of the liquid jet nozzle 21 at which the filler F can be emitted into the gap G of the laminated substrate Ws. In this embodiment, three liquid jet nozzles 21F, 21G, and 21H indicated by black circles in FIG. 5 are arranged in the emitting position, so that these liquid jet nozzles 21F, 21G, and 21H can emit the filler F into the gap G of the laminated substrate Ws.

As shown in FIG. 4, each of the plurality of liquid jet nozzles 21 has, at its distal end, a filler emitting port 22 configured to emit the filler F. An appropriate shape of the filler emitting port 22 is selected based on physical properties (e.g., viscosity, etc.) of the filler F to be applied. At least two filler emitting ports 22 of the plurality of liquid jet nozzles 21 face the gap G between the edge portion E1 of the first substrate W1 and the edge portion E2 of the second substrate W2. In this embodiment, three filler emitting ports 22 of the three liquid jet nozzles 21F, 21G, and 21H face the gap G between the edge portion E1 of the first substrate W1 and the edge portion E2 of the second substrate W2. When the filler F is emitted from the filler emitting ports 22 of the liquid jet nozzles 21F, 21G, and 21H located at the emitting position, the filler F drops toward the gap G of the laminated substrate Ws, and as a result, the filler F can be applied to the gap G of the laminated substrate Ws.

The multi-nozzle head 20 includes a plurality of liquid emitting mechanisms 35 respectively attached to the plurality of liquid jet nozzles 21. Each liquid emitting mechanism 35 is configured to apply a force for each liquid jet nozzle 21 to emit the filler F from the filler emitting port 22. Examples of the liquid emitting mechanism 35 include a piezo element using a piezoelectric effect and an electromagnetic valve using a repulsive force of an electromagnet. A commercially available inkjet nozzle can be used for each of the plurality of liquid jet nozzles 21.

The plurality of liquid emitting mechanisms 35 are electrically coupled to the operation controller 10, and the operation controller 10 can individually instruct the plurality of liquid emitting mechanisms 35 to individually control emitting operations of the plurality of liquid jet nozzles 21. The operation controller 10 is configured to select a liquid jet nozzle 21 to emit the filler F based on the image generated by the imaging device 5 (see FIG. 2) or a predetermined application recipe.

The operation controller 10 issues an emitting signal to the liquid emitting mechanism 35 attached to the liquid jet nozzle 21 to emit, thereby causing the liquid jet nozzle 21 to emit the filler F. While the operation controller 10 issues the emitting signal, the liquid jet nozzle 21 corresponding to the liquid emitting mechanism 35 that received the emitting signal intermittently emits droplets of the filler F from the filler emitting port 22. An amount of the filler F emitted from each liquid jet nozzle 21 per unit time can be regulated by time intervals of emitting signals issued from the operation controller 10 to each liquid emitting mechanism 35. In one embodiment, the time intervals at which the emitting signals are issued may depend on a frequency of a power source (not shown) to be used.

According to this embodiment, since the multi-nozzle head 20 includes the plurality of liquid jet nozzles 21 configured to emit the filler F, a droplet having an appropriate size can be emitted from each liquid jet nozzle 21 without reducing the amount of the filler F emitted per unit time by the multi-nozzle head 20.

In one embodiment, as shown in FIG. 6, the plurality of liquid jet nozzles 21 may be arranged obliquely with respect to the thickness direction of the laminated substrate Ws when viewed from above. In this case, the plurality of liquid jet nozzles 21 are arranged obliquely across the laminated substrate Ws in the thickness direction of the laminated substrate Ws. The arrangement direction of the plurality of liquid jet nozzles 21 is oblique with respect to the rotation axis Ct (not shown in FIG. 6) of the substrate holding device 2. With such an arrangement, the number of the plurality of liquid jet nozzles 21 (indicated by black circles in FIG. 6) located at the emitting position can be increased. Therefore, the filler F can be efficiently applied to the gap G of the laminated substrate Ws.

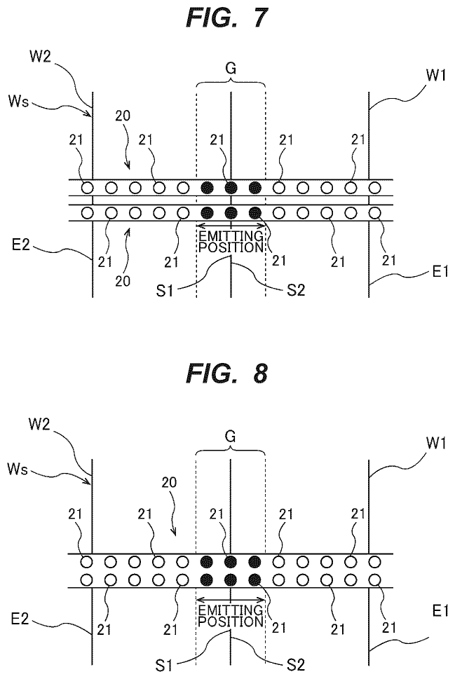

In one embodiment, as shown in FIG. 7, the application system 3 may include a plurality of (in this embodiment, two) multi-nozzle heads 20 arranged in parallel. Alternatively, as shown in FIG. 8, the multi-nozzle head 20 may have a plurality of liquid jet nozzles 21 arranged in a plurality of rows (in this embodiment, two rows). Any of the multi-nozzle heads 20 shown in FIGS. 7 and 8 can increase the number of the plurality of liquid jet nozzles 21 (indicated by black circles in FIGS. 7 and 8) located at the emitting position. Therefore, the filler F can be efficiently applied to the gap G of the laminated substrate Ws.

In one embodiment, the plurality of liquid jet nozzles 21 may be respectively coupled to a plurality of liquid emitting mechanisms each including a combination of a syringe and a piston, instead of the plurality of liquid emitting mechanisms 35.

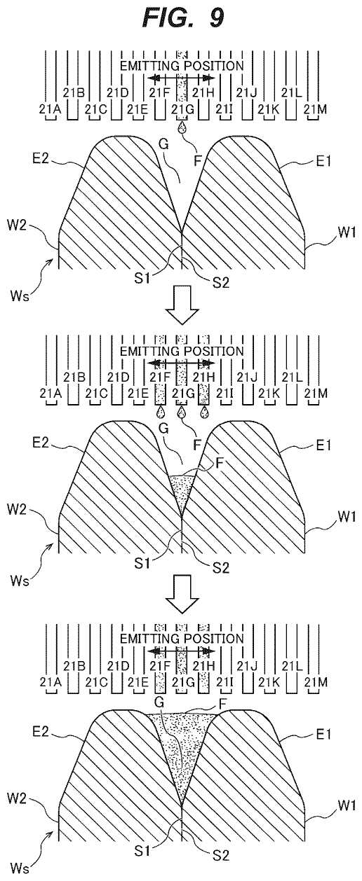

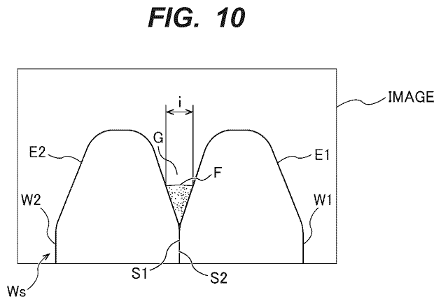

FIG. 9 is a schematic diagram showing an example of a manner in which the plurality of liquid jet nozzles 21 apply the filler F to a gap G of a laminated substrate Ws. In FIG. 9, depiction of the plurality of liquid emitting mechanisms 35 attached to the plurality of liquid jet nozzles 21 is omitted. A shape of the gap G of the laminated substrate Ws increases in width upward from a bottom portion (i.e., ends of the bonding surface S1 of the first substrate W1 and the bonding surface S2 of the second substrate W2). In this embodiment, first, the filler F is emitted from the liquid jet nozzle 21G located in the center of the liquid jet nozzles 21F to 21H located at the emitting position. The filler F is then emitted from the three liquid jet nozzles 21F to 21H located at the emitting position. In this manner, the liquid jet nozzle 21 to emit the filler F is selected according to the shape of the gap G of the laminated substrate Ws. The multi-nozzle head 20 can appropriately apply the filler F to the gap G while adjusting an application amount of the filler F according to the shape of the gap G of the laminated substrate Ws.

The operation controller 10 is configured to switch the liquid jet nozzle 21 to emit the filler F based on a predetermined application recipe. The application recipe is predetermined based on the shape of the gap G of the laminated substrate Ws and the like such that the filler F is appropriately applied to the gap G of the laminated substrate Ws.

In one embodiment, the operation controller 10 may be configured to select, based on the image generated by the imaging device 5 (see FIG. 2), a liquid jet nozzle 21 to emit the filler F from among the plurality of liquid jet nozzles 21. The imaging device 5 generates images of the gap G of the laminated substrate Ws at predetermined time intervals. The image of the gap G of the laminated substrate Ws generated by the imaging device 5 is transmitted to the operation controller 10. FIG. 10 is a schematic diagram showing an example of the image of the gap G of the laminated substrate Ws generated by the imaging device 5. FIG. 10 shows an image generated when the filler F is partially applied to the gap G of the laminated substrate Ws. When the filler F is applied to the gap G of the laminated substrate Ws, the image generated by the imaging device 5 includes an image of the filler F applied to the gap G of the laminated substrate Ws. Therefore, the operation controller 10 can monitor the filler F in the gap G of the laminated substrate Ws based on the image generated by the imaging device 5.

The image generated by the imaging device 5 includes a shape of the filler F in the gap G of the laminated substrate Ws (e.g., a width, a depth, etc. of the filler F in the gap G). The operation controller 10 selects, based on the image generated by the imaging device 5, a liquid jet nozzle 21 to emit the filler F from among the plurality of liquid jet nozzles 21. As in the example shown in FIG. 9, in this embodiment, first, the filler F is emitted from the liquid jet nozzle 21G located in the center of the liquid jet nozzles 21F to 21H located at the emitting position. Next, the operation controller 10 switches the liquid jet nozzle 21 to emit the filler F to the three liquid jet nozzles 21F to 21H based on the image generated by the imaging device 5 when a width of the filler F in the gap G becomes equal to or larger than a predetermined width i shown in FIG. 10. In another embodiment, the operation controller 10 may switch the liquid jet nozzle 21 to emit the filler F to the three liquid jet nozzles 21F to 21H based on the image generated by the imaging device 5 when a depth of the filler F in the gap G becomes equal to or larger than a predetermined depth.

As described above, the imaging device 5 is configured to generate the image of the gap G located at the position P2 upstream of the position P2 directly below the multi-nozzle head 20 (see FIG. 2). The operation controller 10 is configured to determine (calculate) a timing to switch the liquid jet nozzle 21 to emit the filler F based on a rotating speed of the laminated substrate Ws rotated by the substrate holding device 2 and a distance between the position P1 and the position P2.

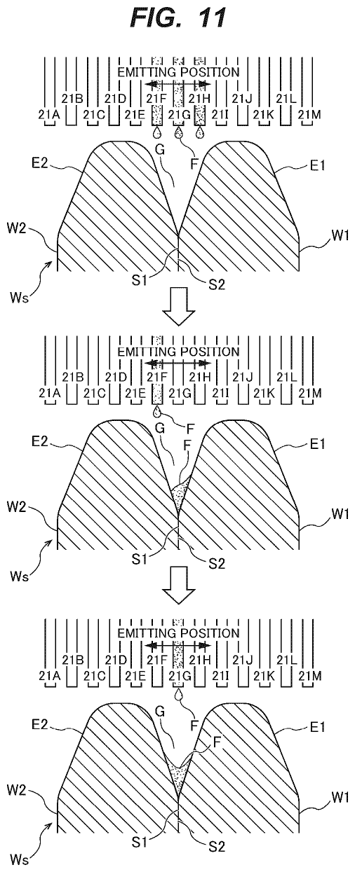

FIG. 11 is a schematic diagram showing another embodiment of the manner in which the plurality of liquid jet nozzles 21 apply the filler F to the gap G of the laminated substrate Ws. Configurations and operations of this embodiment, which will not be particularly described, are the same as those of the above-described embodiments, and duplicated descriptions will be omitted. The filler F applied to the gap G of the laminated substrate Ws may be unevenly deposited in the gap G and may not be uniformly applied. Thus, in this embodiment, the operation controller 10 is configured to select, based on an application state of the filler F in the gap G on the image generated by the imaging device 5, a liquid jet nozzle 21 to emit the filler F from among the plurality of liquid jet nozzles 21. The application state of the filler F includes an unevenness of the filler F in the gap G and the like, and can be obtained from an image in which the filler F in the gap G appears.

In the embodiment shown in FIG. 11, the filler F applied to the gap G from the three liquid jet nozzles 21F to 21H is biased toward the edge portion E1 of the first substrate W1. The operation controller 10 switches the liquid jet nozzle 21 to emit the filler F to a liquid jet nozzle 21F located near the second substrate W2 based on the application state of the filler F in the gap G on the image generated by the imaging device 5. Thereafter, the filler F applied to the gap G of the laminated substrate Ws is biased toward both the edge portion E1 of the first substrate W1 and the edge portion E2 of the second substrate W2, so that a center of the applied filler F is recessed. The operation controller 10 switches the liquid jet nozzle 21 to emit the filler F to the liquid jet nozzle 21G located in the center based on the application state of the filler F in the gap G on the image generated by the imaging device 5. In this manner, the multi-nozzle head 20 can uniformly apply the filler F to the gap G according to the application state of the filler F applied to the gap G.

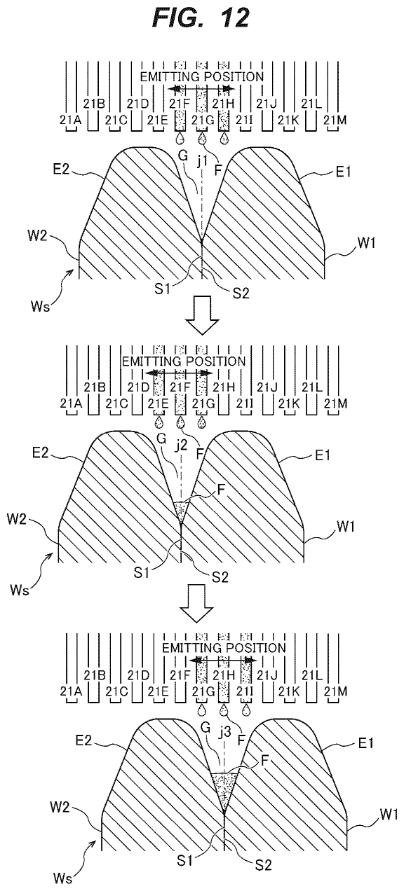

FIG. 12 is a schematic diagram showing still another embodiment of the manner in which the plurality of liquid jet nozzles 21 apply the filler F to the gap G of the laminated substrate Ws. Configurations and operations of this embodiment, which will not be particularly described, are the same as those of the above-described embodiments, and duplicated descriptions will be omitted. As shown in FIG. 12, during the application of the filler F to the gap G of the laminated substrate Ws, the position of the gap G may fluctuate in the thickness direction of the laminated substrate Ws due to a surface deflection of the laminated substrate Ws with rotation of the laminated substrate Ws. Thus, in this embodiment, the operation controller 10 is configured to detect a position of the gap G in the thickness direction of the laminated substrate Ws based on the image generated by the imaging device 5, and to select the liquid jet nozzle 21 to emit the filler F from among the plurality of liquid jet nozzles 21 based on the detected position of the gap G.

Since the position of the imaging device 5 is fixed, the operation controller 10 can detect the position of the gap G appearing on the image from a position on an image of the gap G of the laminated substrate Ws at a known position and a correlation between a distance on the image and an actual distance. The position of the gap G may be the deepest portion of the gap G of the laminated substrate Ws appearing on the image, or may be an intermediate point in the thickness direction of the laminated substrate Ws appearing on the image. In this embodiment, the position of the gap G is the deepest portion of the gap G of the laminated substrate Ws appearing on the image.

In the embodiment shown in FIG. 12, the position of the gap G of the laminated substrate Ws changes from a position j1 to a position j2, and then changes to a position j3. When the gap G of the laminated substrate Ws is located at the position j1, the three liquid jet nozzles 21F to 21H are in the emitting position. When the gap G of the laminated substrate Ws is located at the position j2, the three liquid jet nozzles 21E to 21G are in the emitting position. When the gap G of the laminated substrate Ws is located at the position j3, the three liquid jet nozzles 21G to 21I are in the emitting position.

When the detected position of the gap G is the position j1, the operation controller 10 selects the liquid jet nozzles 21F to 21H as the liquid jet nozzles to emit the filler F. When the detected position of the gap G is the position j2, the operation controller 10 selects the liquid jet nozzles 21E to 21G as the liquid jet nozzles to emit the filler F. When the detected position of the gap G is the position j3, the operation controller 10 selects the liquid jet nozzles 21G to 21I as the liquid jet nozzles to emit the filler F. Therefore, the multi-nozzle head 20 can follow the position of the gap G of the laminated substrate Ws, so that the filler F can be applied appropriately.

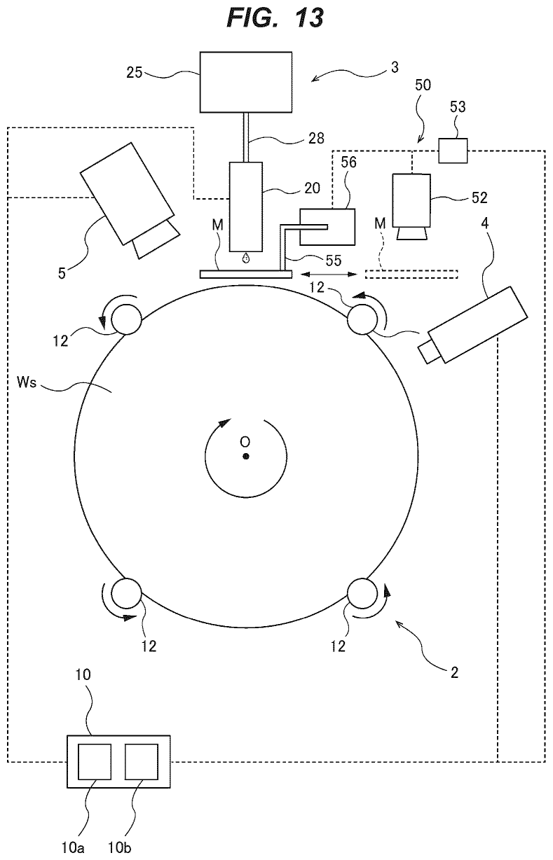

FIG. 13 is a schematic diagram showing another embodiment of the application system 3. Configurations and operations of this embodiment, which will not be particularly described, are the same as those of the above-described embodiments, and duplicated descriptions will be omitted. In the multi-nozzle head 20, an abnormality may occur in a part of the plurality of liquid jet nozzles 21, such as clogging of a nozzle due to sticking of the filler F over time during use. Thus, the application system 3 of this embodiment further includes an abnormality detection device 50 configured to detect an abnormality in the plurality of liquid jet nozzles 21. The abnormality detection device 50 includes an abnormality detection imaging device 52 configured to generate an image of a test plate M, an abnormality detection section 53 configured to detect an abnormality in the plurality of liquid jet nozzles 21 based on the image generated by the abnormality detection imaging device 52, a plate holder 55 configured to hold the test plate M, and a plate moving mechanism 56 configured to move the test plate M.

The test plate M is a plate for performing test application of the filler F in order to detect an abnormality in the plurality of liquid jet nozzles 21. The test plate M is held by the plate holder 55. The plate moving mechanism 56 is coupled to the plate holder 55, and is configured to move the test plate M between a test-plate application position below the multi-nozzle head 20 and a test-plate imaging position below the abnormality detection imaging device 52. The test-plate application position is a position of the test plate M at which the plurality of liquid jet nozzles 21 of the multi-nozzle head 20 can emit the filler F onto a surface of the test plate M (indicated by a solid line in FIG. 13). The test-plate imaging position is a position of the test plate M at which the abnormality detection imaging device 52 can generate an image of the test plate M to which the filler F is applied (indicated by a dashed line in FIG. 13).

The abnormality detection section 53 is coupled to the abnormality detection imaging device 52, and is configured to detect an abnormality in the plurality of liquid jet nozzles 21 based on the image of the test plate M generated by the abnormality detection imaging device 52. The abnormality detection section 53 is coupled to the operation controller 10, and a detection result of the abnormality by the abnormality detection section 53 is transmitted to the operation controller 10.

The abnormality detection section 53 includes a memory (not shown) storing programs therein, and an arithmetic device (not shown) configured to perform arithmetic operations according to instructions contained in the programs. The arithmetic device includes a CPU (Central Processing Unit) or a GPU (Graphic Processing Unit) that performs calculations according to instructions included in the program. The memory includes a main memory (e.g., a random access memory) accessible by the arithmetic device, and an auxiliary memory (e.g., a hard disk drive or a solid state drive) configured to store data and the programs. However, the specific configuration of the abnormality detection section 53 is not limited to these examples. The abnormality detection section 53 may be composed of at least one computer. In one embodiment, the abnormality detection section 53 may be configured integrally with the operation controller 10.

The abnormality detection imaging device 52 and the plate moving mechanism 56 are electrically coupled to the operation controller 10, and operations of the abnormality detection imaging device 52 and the plate moving mechanism 56 are controlled by the operation controller 10.

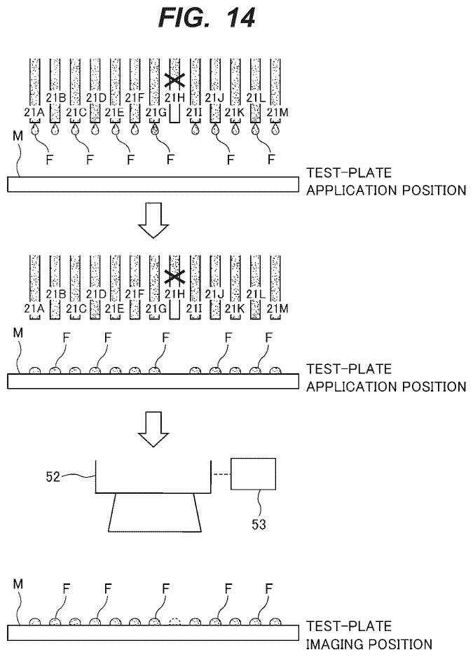

FIG. 14 is a diagram illustrating an embodiment of a method of detecting an abnormality in the plurality of liquid jet nozzles 21. First, the filler F is emitted from the plurality of liquid jet nozzles 21 (in this embodiment, the plurality of liquid jet nozzles 21A to 21M) toward the surface of the test plate M located at the test-plate application position, and test application of the filler F is performed onto the test plate M. In this embodiment, since an abnormality has occurred in the liquid jet nozzle 21H, the filler F is not emitted from the liquid jet nozzle 21H. Next, the test plate M is moved to the test-plate imaging position by the plate moving mechanism 56 described with reference to FIG. 13, and an image of the test plate M is then generated by the abnormality detection imaging device 52.

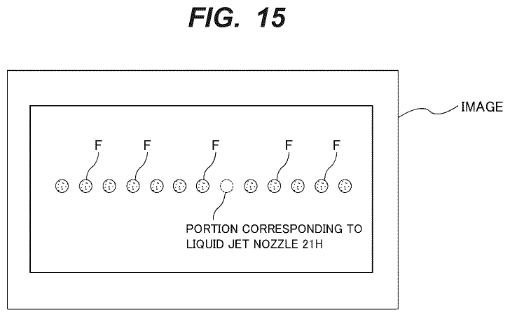

FIG. 15 is a schematic diagram showing an example of an image of the test plate M subjected to test application generated by the abnormality detection imaging device 52. As shown in FIG. 15, in the image of the test plate M generated by the abnormality detection imaging device 52, the filler F emitted from the plurality of liquid jet nozzles 21A to 21G and 21I to 21M appears. However, the filler F does not appear on the image in a portion corresponding to the liquid jet nozzle 21H in which the abnormality has occurred. The abnormality detection section 53 identifies the liquid jet nozzle 21H corresponding to the portion where the filler F does not appear based on the image of the test plate M generated by the abnormality detection imaging device 52, and detects the abnormality in the liquid jet nozzle 21H. In this manner, the abnormality detection device 50 can detect the abnormality in the plurality of liquid jet nozzles 21.

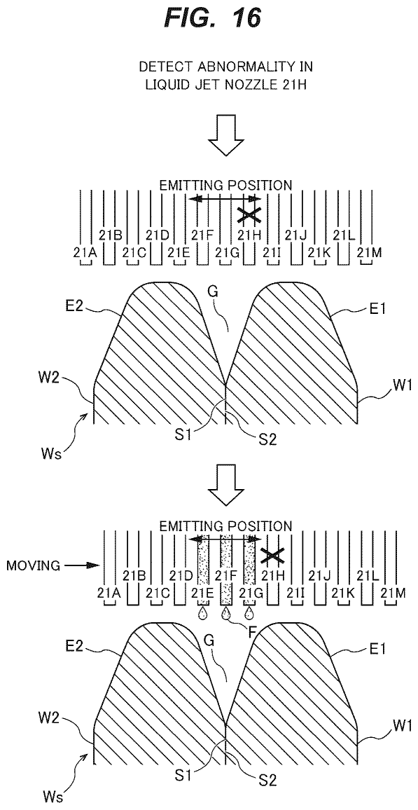

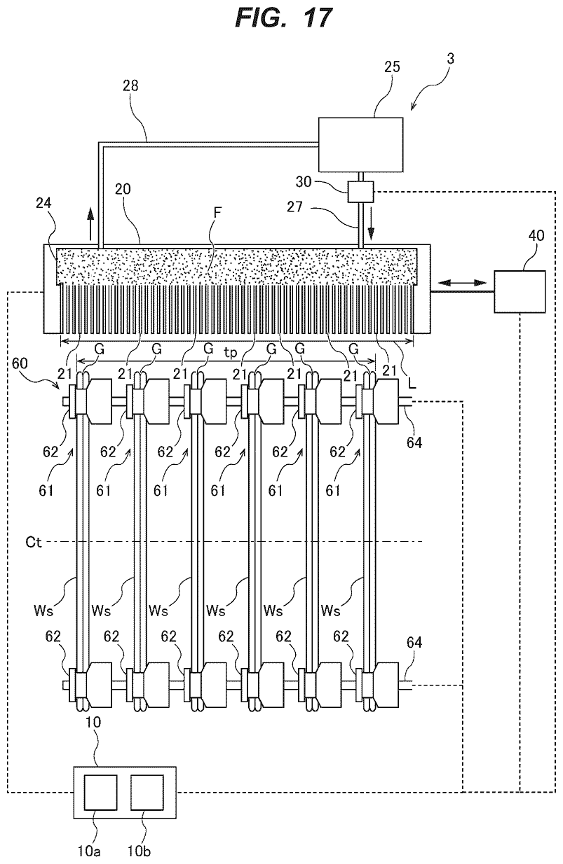

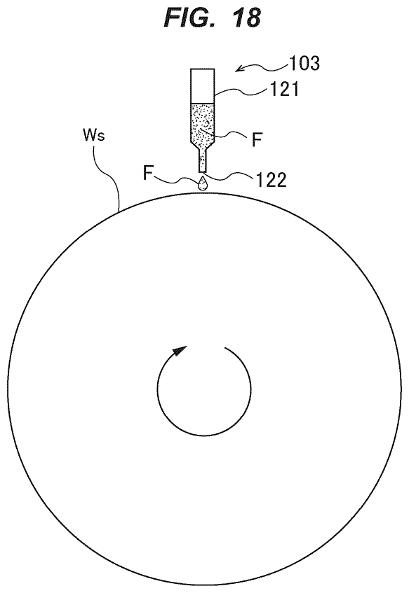

FIG. 16 is a diagram illustrating an embodiment of a method of moving the plurality of liquid jet nozzles 21A to 21M when the abnormality is detected in the liquid jet nozzle 21H by the abnormality detection device 50. In this embodiment, detection of the abnormality in the plurality of liquid jet nozzles 21 by the abnormality detection device 50 is performed while a laminated substrate that has been previously processed is transported to another apparatus and a laminated substrate Ws to be processed next is transported. As described above, when the abnormality is detected in the liquid jet nozzle 21H by the abnormality detection device 50, a detection result of the abnormality is transmitted to the operation controller 10. The detection result of the abnormality includes information capable of identifying the liquid jet nozzle 21 in which the abnormality has been detected (e.g., an identification number assigned to each liquid jet nozzle 21, etc.). In this embodiment, the detection result that the abnormality has occurred in the liquid jet nozzle 21H is transmitted from the abnormality detection device 50 to the operation controller 10.

Before starting application of the filler F to the laminated substrate Ws to be processed next, the operation controller 10 is configured to move, based on the detection result of the abnormality sent from the abnormality detection device 50, the plurality of liquid jet nozzles 21 of the multi-nozzle head 20 by the above-described nozzle moving mechanism 40 (see FIG. 3) such that the liquid jet nozzle 21H in which the abnormality has been detected moves in a direction away from the emitting position facing the gap G of the laminated substrate Ws. In this embodiment, the plurality of liquid jet nozzles 21 of the multi-nozzle head 20 are moved toward the first substrate W1 in the thickness direction of the laminated substrate Ws, so that the liquid jet nozzle 21H in which the abnormality has been detected is located outside the emitting position. The liquid jet nozzle 21H in which the abnormality has been detected is located at a position not facing the gap G of the laminated substrate Ws. The liquid jet nozzles 21E to 21G in which no abnormality has occurred are located in the emitting position.

According to this embodiment, when an abnormality occurs in any of the plurality of liquid jet nozzles 21, the multi-nozzle head 20 can continue applying the filler F to the gap G of the laminated substrate Ws by using other liquid jet nozzles 21 in which no abnormality has occurred. As a result, the filler F can be stably applied to the gap G between the edge portion E1 of the first substrate W1 and the edge portion E2 of the second substrate W2. The detection of the abnormality in the plurality of liquid jet nozzles 21 by the abnormality detection device 50 may be performed every time one laminated substrate is processed, or may be performed every time multiple laminated substrates are processed.

FIG. 17 is a schematic diagram showing another embodiment of the substrate processing apparatus. Configurations and operations of this embodiment, which will not be particularly described, are the same as those of the above-described embodiments, and duplicated descriptions will be omitted. The multi-nozzle head 20 of this embodiment can apply the filler F to a plurality of laminated substrates Ws in parallel. A substrate holding device 60 of this embodiment includes a plurality of (in this embodiment, six) substrate holding mechanisms 61 configured to respectively hold and rotate the plurality of (in this embodiment, six) laminated substrates Ws, and a plurality of (in this embodiment, four) coupling shafts 64 configured to couple the plurality of substrate holding mechanisms 61. Each substrate holding mechanism 61 includes a plurality of (in this embodiment, four) rollers 62 which can contact a periphery of the laminated substrate Ws. In this embodiment, each substrate holding mechanism 61 includes four rollers 62, while each substrate holding mechanism 61 may include three rollers, or five or more rollers.

The four rollers 62 of each substrate holding mechanism 61 contact the periphery of the laminated substrate Ws to hold the laminated substrate Ws such that a flat portion of the laminated substrate Ws is perpendicular to the horizontal plane. Therefore, the plurality of laminated substrates Ws are held in a vertical posture by the plurality of substrate holding mechanisms 61. The four coupling shafts 64 extend parallel to the rotation axis Ct of the substrate holding device 60 such that four axes of the four rollers 62 of each substrate holding mechanism 61 respectively coincide with four axes of the four coupling shafts 64. Each coupling shaft 64 extends through six rollers 62 whose axes coincide with each other via through-holes (not shown) formed in each roller 62. Each coupling shaft 64 and the six rollers 62 whose axes coincide with an axis of the coupling shaft 64 are fixed to each other.

The substrate holding device 60 includes a coupling-shaft rotating mechanism (not shown) configured to rotate each of the coupling shafts 64 about their respective own axes. The coupling-shaft rotating mechanism is coupled to the four rotating shafts 64, and is configured to rotate the four rotating shafts 64 in the same direction at the same speed. The four rotating shafts 64 are rotated by the coupling-shaft rotating mechanism, so that the four rollers 62 of each substrate holding mechanism 61 rotate together with the four rotating shafts 64, and the plurality of laminated substrates Ws are rotated together about the rotation axis Ct of the substrate holding device 60. The configuration of the coupling-shaft rotating mechanism is not limited as long as the coupling-shaft rotating mechanism can rotate the plurality of rotating shafts 64 in the same direction at the same speed, and any known rotating mechanism can be used as the coupling-shaft rotating mechanism. An example of the coupling-shaft rotating mechanism is a combination of a motor, pulleys (and/or gears), and a rotating belt.

The multi-nozzle head 20 is located radially outwardly of the plurality of laminated substrates Ws held by the substrate holding device 60, and is arranged above the plurality of laminated substrates Ws. At least a part of the plurality of liquid jet nozzles 21 of the multi-nozzle head 20 is arranged in a plurality of emitting positions facing a plurality of gaps G of the plurality of laminated substrates Ws. Since the plurality of laminated substrates Ws are arranged at predetermined intervals, the plurality of emitting positions corresponding to the plurality of gaps G of the plurality of laminated substrates Ws are located at predetermined intervals. Therefore, a part of the plurality of liquid jet nozzles 21 are arranged in positions not facing any of the plurality of gaps G of the plurality of laminated substrates Ws. Each of the plurality of emitting positions facing the plurality of gaps G of the plurality of laminated substrates Ws is the same as the emitting position of the laminated substrate Ws described with reference to FIGS. 4 and 5, and duplicated descriptions will be omitted.

The plurality of liquid jet nozzles 21 of the multi-nozzle head 20 are arranged along the rotation axis Ct of the substrate holding device 60. An arrangement direction of the plurality of liquid jet nozzles 21 is parallel to the rotation axis Ct of the substrate holding device 60 or is oblique with respect to the rotation axis Ct of the substrate holding device 60. In this embodiment, the arrangement direction of the plurality of liquid jet nozzles 21 is parallel to the rotation axis Ct of the substrate holding device 60. The plurality of liquid jet nozzles 21 are arranged across the plurality of laminated substrates Ws in a thickness direction of the plurality of laminated substrates Ws held by the substrate holding device 60. An arrangement length L of the plurality of liquid jet nozzles 21 is larger than a total thickness tp of the plurality of laminated substrates Ws. The arrangement length L of the plurality of liquid jet nozzles 21 is a distance between two liquid jet nozzles 21 located at both ends, and includes widths of the two liquid jet nozzles 21 themselves located at both ends. The total thickness tp of the plurality of laminated substrates Ws is a distance between two laminated substrates Ws located at both ends, and includes widths of the two laminated substrates Ws themselves located at both ends.

The plurality of liquid jet nozzles 21 arranged in the plurality of emitting positions emit the filler F to the plurality of gaps G of the plurality of laminated substrates Ws. According to this embodiment, the multi-nozzle head 20 can apply the filler F to the plurality of laminated substrates Ws held by the substrate holding device 60 in parallel. As a result, the substrate processing apparatus can improve throughput of an application process of the filler F to the laminated substrate Ws.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a substrate processing apparatus for applying filler to a gap between edge portions of substrates constituting a laminated substrate.

### REFERENCE SIGNS LIST

2 substrate holding device
3 application system
4 curing device
5 imaging device

110 operation controller
10a memory
10b processor
12 roller
20 multi-nozzle head
21, 21A to 21M liquid jet nozzle
22 filler emitting port
24 filler chamber
25 filler supply source
27 filler supply line
28 filler return line
30 flow-rate regulating device
35, 35A to 35M liquid emitting mechanism
40 nozzle moving mechanism
50 abnormality detection device
52 abnormality detection imaging device
53 abnormality detection section
55 plate holder
56 plate moving mechanism
60 substrate holding device
61 substrate holding mechanism
62 roller
64 rotating shaft
W1 first substrate
W2 second substrate
Ws laminated substrate
E1, E2 edge portion
F filler
G gap
M test plate

1. A substrate processing apparatus for applying a filler to a laminated substrate having a first substrate and a second substrate bonded to each other, comprising:
a substrate holding device configured to hold and rotate the laminated substrate; and
a multi-nozzle head configured to apply the filler to a gap between an edge portion of the first substrate and an edge portion of the second substrate,
wherein the multi-nozzle head includes a plurality of liquid jet nozzles configured to emit the filler, and
the plurality of liquid jet nozzles are arranged along a rotation axis of the substrate holding device.

2. The substrate processing apparatus according to claim 1, wherein the plurality of liquid jet nozzles are arranged across the laminated substrate in a thickness direction of the laminated substrate held by the substrate holding device.

3. The substrate processing apparatus according to claim 1, wherein an arrangement pitch of the plurality of liquid jet nozzles is smaller than a width of the gap.

4. The substrate processing apparatus according to claim 3, wherein at least two of the plurality of liquid jet nozzles are arranged in an emitting position facing the gap.

5. The substrate processing apparatus according to claim 1, wherein an arrangement length of the plurality of liquid jet nozzles is larger than a thickness of the laminated substrate.

6. The substrate processing apparatus according to claim 1, further comprising:
an operation controller configured to individually control emitting operations of the plurality of liquid jet nozzles.

7. The substrate processing apparatus according to claim 6, further comprising:
an imaging device configured to generate an image of the gap,
wherein the operation controller is configured to select, based on the image, a liquid jet nozzle to emit the filler from among the plurality of liquid jet nozzles.

8. The substrate processing apparatus according to claim 7, wherein the operation controller is configured to select, based on an application state of the filler in the gap on the image, a liquid jet nozzle to emit the filler from among the plurality of liquid jet nozzles.

9. The substrate processing apparatus according to claim 7, wherein
the operation controller is configured to:
detect a position of the gap in a thickness direction of the laminated substrate based on the image, and
select, based on the detected position of the gap, a liquid jet nozzle to emit the filler from among the plurality of liquid jet nozzles.

10. the substrate processing apparatus according to claim 7, wherein the imaging device is arranged upstream of the plurality of liquid jet nozzles in a rotation direction of the laminated substrate.

11. The substrate processing apparatus according to claim 6, further comprising:
a nozzle moving mechanism configured to move the plurality of liquid jet nozzles; and
an abnormality detection device configured to detect an abnormality in the plurality of liquid jet nozzles,
wherein the operation controller is configured to control an operation of the nozzle moving mechanism, and
the operation controller is configured to cause the nozzle moving mechanism to move the plurality of liquid jet nozzles such that a liquid jet nozzle in which an abnormality has been detected by the abnormality detection device moves in a direction away from an emitting position facing the gap.

12. The substrate processing apparatus according to claim 1, wherein the plurality of liquid jet nozzles are arranged obliquely with respect to a thickness direction of the laminated substrate held by the substrate holding device.

13. The substrate processing apparatus according to claim 1, wherein
the substrate holding device includes a plurality of substrate holding mechanisms configured to hold and rotate a plurality of laminated substrates, and
at least a part of the plurality of liquid jet nozzles is arranged in a plurality of emitting positions facing a plurality of gaps of the plurality of laminated substrates.

14. The substrate processing apparatus according to claim 13, wherein the plurality of liquid jet nozzles are arranged across the plurality of laminated substrates in a thickness direction of the plurality of laminated substrates held by the plurality of substrate holding mechanisms.
